(19) United States
(12) Patent Application Publication
(10) Pub. No.: US 2015/0079705 A1
(43) Pub. Date: Mar. 19, 2015

(54) METHOD OF MANUFACTURING CONTAMINATION LEVEL OF ION IMPLANTING APPARATUS

(71) Applicant: SAMSUNG ELECTRONICS CO., LTD., SUWON-SI (KR)

(72) Inventors: Sooman Kim, Hwaseong-si (KR); Wonseok Yang, Yongin-si (KR)

(21) Appl. No.: 14/314,642

(22) Filed: Jun. 25, 2014

(30) Foreign Application Priority Data
Sep. 16, 2013 (KR) 10-2013-0111391

(51) Int. Cl. H01L 21/66

(52) U.S. Cl. CPC H01L 22/14
USPC 438/17

(57) ABSTRACT

A method of measuring a contamination level of an ion implanting apparatus is disclosed. The method may include the steps of providing a wafer, forming a first layer on the wafer, injecting impurities into the first layer, preparing an analysis sample by removing the first layer and concurrently collecting the impurities captured in the first layer from the wafer, and analyzing the analysis sample.

### CROSS-REFERENCE TO RELATED APPLICATIONS

This U.S. non-provisional patent application claims priority under 35 U.S.C. §119 to Korean Patent Application No. 10-2013-0111391, filed on Sep. 16, 2013, in the Korean Intellectual Property Office, the entire contents of which are hereby incorporated by reference.

### BACKGROUND OF THE INVENTION

Embodiments of the inventive concept relate to a method of measuring a contamination level of an apparatus used for fabricating a semiconductor device, and in particular, to a method of measuring a contamination level of an ion implanting apparatus.

A semiconductor wafer, which is used as a base substrate of semiconductor devices, is treated with various process gases and cleaning solutions. To prevent the semiconductor wafer from being contaminated, a process gas and a cleaning solution having ultra-high purity should be used in the fabrication of the semiconductor devices. However, after a fabricating process, traces of impurities (e.g., metallic ions) may remain on the semiconductor wafer, and it becomes increasingly important to control a contamination level and to identify the kinds of such impurities and any contamination sources.

Such contamination should be avoided because, when the semiconductor wafer is contaminated by impurities (e.g., metallic ions), CMOS image sensor (CIS) may suffer from a chip failure, such as a white spot failure.

### SUMMARY

Some embodiments of the inventive concept provide a method of measuring a contamination level of an ion implanting apparatus with increased accuracy and thereby provide a more reliable analysis result.

According to some embodiments of the inventive concept, a method of measuring a contamination level of an ion implanting apparatus may include the steps of providing a wafer, forming a first layer on the wafer, injecting impurities into the first layer using the ion implanting apparatus, preparing a analysis sample by removing the first layer and concurrently collecting the impurities captured in the first layer from the wafer, and analyzing the analysis sample.

In some embodiments, the step of forming the first layer on the wafer may include performing a diffusion process on the wafer.

In some embodiments, the first layer may be formed of a silicon oxide layer or a silicon nitride layer.

In some embodiments, the step of injecting the impurities into the first layer may include loading the wafer provided with the first layer into an ion implanting apparatus and performing an ion implantation process on the wafer.

In some embodiments, the impurities may include metallic elements produced in the ion implanting apparatus.

In some embodiments, the ion implanting apparatus may include an ion source part and a cathode provided in the ion source part, and the impurities may include metallic elements originating from the cathode.

In some embodiments, the impurities may include at least one of tungsten (W), iron (Fe), molybdenum (Mo), nickel (Ni), aluminum (Al), cadmium (Cd), or copper (Cu).

In some embodiments, some of the impurities may be cationized in the ion source part and be injected into the first layer on the wafer during the step of injecting the impurities.

In some embodiments, during the ion implantation process, some of the impurities may be cationized and may be captured by the first layer on the wafer.

In some embodiments, the step of preparing the sample may include dissolving the first layer containing the impurities with a dissolving solution, and collecting the resulting solution, which includes the impurities from the wafer dissolved in the solution, as the analysis sample.

In some embodiments, the dissolving solution may include at least one of hydrofluoric acid (HF), hydrochloric acid (HCl), nitric acid (HNO₃), or hydrogen peroxide (H₂O₂).

In some embodiments, the step of analyzing the analysis sample may include measuring a concentration of the impurities in the analysis sample.

In some embodiments, the step of analyzing the analysis sample may be performed using an inductively-coupled-plasma mass spectrometer (ICP-MS).

In another aspect, a method for periodically monitoring the contamination level of an ion implanting apparatus used to implant ions in a semiconductor substrate includes the steps of: periodically placing a substrate having a dissolvable, impurity-absorbing layer on a substrate surface in the ion implanting apparatus; subjecting the substrate surface with the dissolvable layer thereon to an ion implantation process using the ion implantation apparatus; capturing impurities from the ion implanting apparatus in the dissolvable layer; removing the dissolvable layer, together with any captured impurities, from the substrate by dissolving the layer in a solvent; and, measuring the concentration of impurities in the solvent containing the dissolved impurity-absorbing layer.

In an embodiment, the substrate is a silicon wafer, the dissolvable, impurity-absorbing layer is formed of silicon oxide or silicon nitride, and the solvent is selected from the group consisting of hydrofluoric acid, hydrochloric acid, nitric acid, hydrogen peroxide and mixtures thereof.

In an embodiment, the thickness of the dissolvable, impurity-absorbing layer is about 100 Å or greater.

In an embodiment, the concentration of impurities in the solvent containing the dissolved layer is measured using an inductively-coupled-plasma mass spectrometer (ICP-MS).

In another aspect, a method for fabricating a semiconductor device that includes a semiconductor wafer that is doped using an ion implanting apparatus includes the steps of: measuring the contamination levels of one or more ion implanting apparatuses by providing a wafer, forming a first layer on the wafer, injecting impurities into the first layer using the ion implanting apparatus, preparing an analysis sample by removing the first layer and concurrently collecting the impurities captured in the first layer from the wafer, and analyzing the analysis sample; selecting an ion implanting apparatus that demonstrates no or a very low contamination level; and, preparing the doped semiconductor wafer using the ion implanting apparatus with the very low or no contamination level.

### BRIEF DESCRIPTION OF THE DRAWINGS

Exemplary embodiments will be more clearly understood from the following brief description taken in conjunction with the accompanying drawings. It will be understood that the accompanying drawings represent some non-limiting, exemplary embodiments as described herein.

FIG. 1 is a flow chart illustrating a method of measuring a contamination level of an ion implanting apparatus according to some embodiments of the inventive concept.

FIGS. 2, 3, and 5 are diagrams schematically illustrating a method of measuring a contamination level of an ion implanting apparatus according to some embodiments of the inventive concept.

FIG. 4 is an enlarged view of a portion A of the apparatus of FIG. 3.

It should be noted that these figures are intended to illustrate the general characteristics of methods, structure and/or materials utilized in certain exemplary embodiments and to supplement the written description provided below. These drawings are not, however, to scale and may not precisely reflect the precise structural or performance characteristics of any given embodiment, and therefore should not be interpreted as defining or limiting the range of values or properties encompassed by the illustrated embodiments. For example, the relative thicknesses and positioning of molecules, layers, regions and/or structural elements may be reduced or exaggerated for clarity. The use of similar or identical reference numbers in the various drawings is intended to indicate a similar or identical element or feature.

### DETAILED DESCRIPTION

Exemplary embodiments of the inventive concepts will now be described more fully with reference to the accompanying drawings, in which some embodiments are shown. Exemplary embodiments of the inventive concepts may, however, be embodied in many different forms and should not be construed as being limited to the embodiments set forth herein; rather, these embodiments are provided so that this disclosure will be thorough and complete, and will fully convey the concept of these exemplary embodiments to those of ordinary skill in the art. In the drawings, the thicknesses of layers and regions are exaggerated for clarity. Like reference numerals in the drawings denote like elements, and thus their descriptions in connection with subsequent drawings will be omitted or abbreviated.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in the same way as discussed above (e.g., “between” versus “directly between,” “adjacent” versus “directly adjacent,” “on” versus “directly on”).

It will also be understood that, although the terms “first”, “second”, etc. may be used herein to describe various elements, components, regions, layers and/or sections, these elements, components, regions, layers and/or sections are not intended to be limited by these terms. These terms are only used to distinguish one element, component, region, layer or section from another element, component, region, layer or section. Thus, a first element, component, region, layer or section discussed below could be termed a second element, component, region, layer or section without departing from the teachings of the illustrated embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may also be otherwise oriented (rotated 90 degrees or at other orientations) and the spatially relative descriptors used herein are intended to be interpreted accordingly.

The terminology used herein is for the purpose of describing particular embodiments only and is not intended to be limiting of the exemplary embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which the exemplary embodiments of the inventive concepts belong. It will be further understood that terms, such as those defined in commonly-used dictionaries, should be interpreted as having a meaning that is consistent with their meaning in the context of the relevant art and these terms should not be interpreted in an idealized or overly formal sense unless expressly so defined herein.

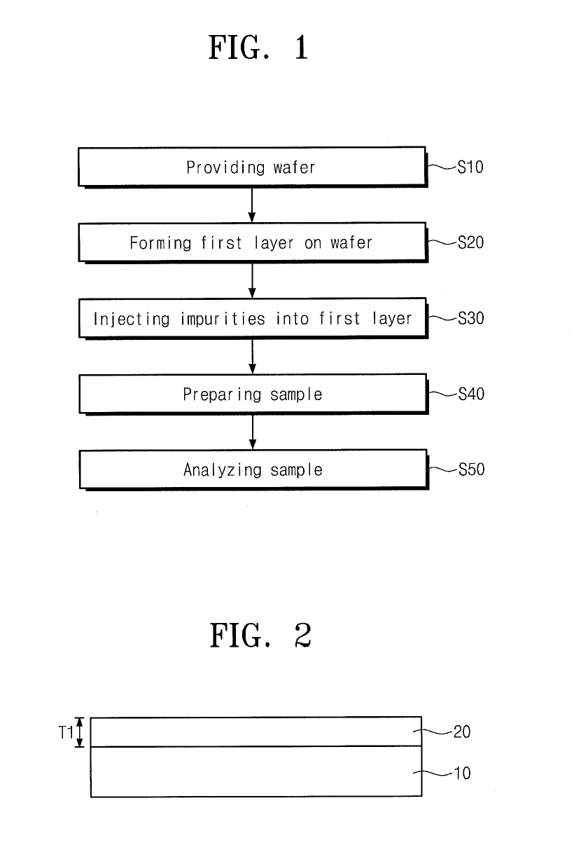

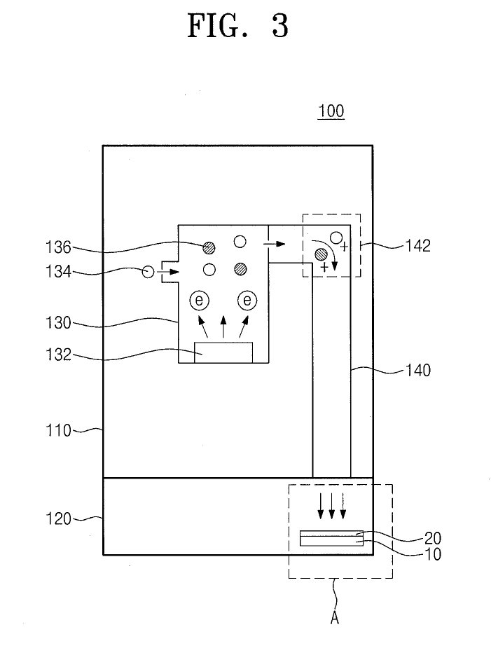

FIG. 1 is a flow chart illustrating a method of measuring a contamination level of an ion implanting apparatus according to some embodiments of the inventive concept, and FIGS. 2, 3, and 5 are diagrams schematically illustrating a method of measuring a contamination level of an ion implanting apparatus according to some embodiments of the inventive concept.

Referring to FIGS. 1 and 2, a wafer 10 is provided (in S10). For example, the wafer 10 may be a silicon wafer. A first layer 20 may be formed on the wafer 10 (in S20). The step of forming the first layer 20 may include performing a diffusion process to the wafer 10. The first layer 20 may be a silicon oxide layer or a silicon nitride layer. The first layer 20 may be formed to have a first thickness T1 (FIG. 2), which may be equal to or thicker than about 100 Å.

Referring to FIGS. 1 and 3, impurities may be injected into the first layer 20 (in S30). The injection of the impurities into the first layer 20 may include the steps of loading the wafer 10 (provided with the first layer 20) into an ion implanting apparatus 100, whose contamination level is to be measured, and then performing an ion implantation process to the wafer 10 and first layer 20. The ion implanting apparatus 100 may include, for example, an ion generating part 110 and a processing part 120. The ion generating part 110 may include an ion source part 130 with a cathode 132 and an ion transfer path 140 in combination with a magnet analyzer 142. The wafer 10 having the first layer 20 may be provided in the processing part 120 of the apparatus 100.

The ion implantation process to the wafer 10 and first layer 20 may include a step of supplying a gas containing first impurities 134 into the ion source part 130. The first impurities 134 may include dopant atoms which can serve as donors or acceptors in the semiconductor wafer. For example, the first impurities 134 may include boron (B), phosphorus (P), or arsenic (As). The first impurities 134 may be cationized by electrons (denoted by the letter “e” in FIG. 3) emitted from the cathode 132.

There may also be second impurities 136 in the ion source part 130. The second impurities 136 may be substances that adversely affect the performance characteristics of the semiconductor device. For example, the cathode 132 may be made of a metallic material, and the second impurities 136 in ion source part 130 of the apparatus 100 may include metallic elements which originate from the cathode 132 or, alternatively, from elsewhere in the apparatus. For example, the second impurities 136 may include at least one of tungsten (W), iron (Fe), molybdenum (Mo), nickel (Ni), aluminum (Al), cadmium (Cd), or copper (Cu). The second impurities 136 may be cationized by other impurities (e.g., fluorine F) existing in the ion source part 130.

The first and second cationized impurities 134 and 136, respectively, may pass through the magnet analyzer 142 with a similar trajectory that directs them to the processing part 120 of the apparatus 100.

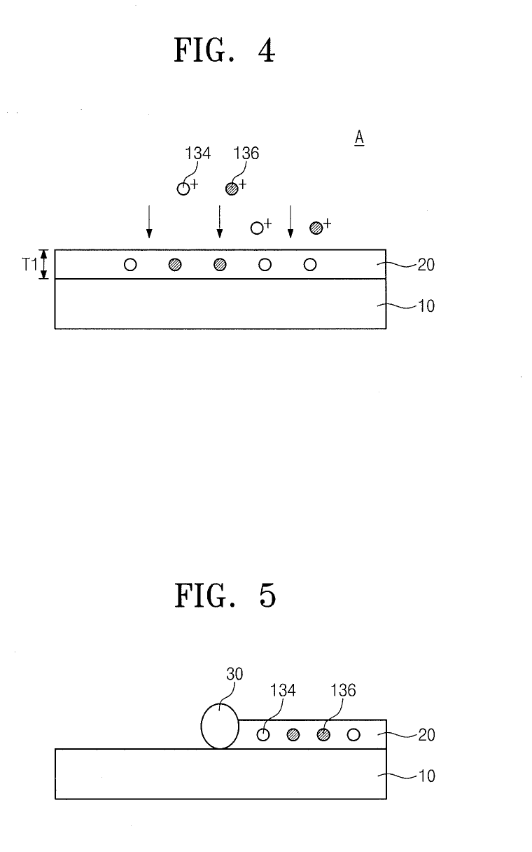

FIG. 4 is an enlarged view of a portion A of the apparatus illustrated in FIG. 3. Referring to FIG. 4, during the ion implantation process, the cationized impurities 134 and 136 provided into the processing part 120 may be captured by the first layer 20 on the wafer 10. In this case, the first layer 20 may have a predetermined thickness (e.g., the first thickness T1), which is selected to prevent the cationized impurities 134 and 136 from penetrating through the first layer 20 and reaching the wafer 10. As an example, the first thickness T1 may be equal to or greater than about 100 Å. However, the first thickness T1 may vary depending on the type of ion implanting apparatus 100 and on the process conditions of the ion implantation process. For example, the thickness of the first layer 20 may need to be greater in a high energy ion implanting apparatus than in a low energy ion implanting apparatus.

In a case where the wafer 10 provided in the processing part 120 does not include the first layer 20, the cationized impurities 134 and 136, which are passed through the magnet analyzer 142 with a similar trajectory, may be simultaneously injected into the wafer 10 during the ion implantation process. If the second impurities 136 (originating from the cathode 132 or from elsewhere in the apparatus 100) are injected into the wafer 10, it may be difficult to detect the presence of those second impurities 136 in subsequent steps used for measuring the contamination level of the ion implanting apparatus 100.

According to some embodiments of the inventive concept, however, since the first layer 20 with a predetermined thickness is provided on the wafer 10 during the ion implantation process, the cationized impurities 134 and 136 may be captured by the first layer 20. Accordingly, the presence of the second impurities 136 can be easily detected in the subsequent steps for measuring the contamination level of the ion implanting apparatus 100.

Referring to FIGS. 1 and 5, an analysis sample may be prepared in order to analyze the impurities 134 and 136 captured in the first layer 20 (in S40). The sample may be prepared by removing the first layer 20 and concurrently collecting the impurities 134 and 136 captured in first layer 20. For example, the preparation of the sample may include the steps of providing a solution 30 to the wafer 10 to dissolve the first layer 20, including the captured impurities 134 and 136, and then, collecting the solution 30, in which the impurities 134 and 136 are dissolved, from the wafer 10. The solution 30 may include at least one of hydrofluoric acid (HF), hydrochloric acid (HCl), nitric acid (HNO₃), or hydrogen peroxide (H₂O₂).

Referring back to FIG. 1, the analysis sample may be analyzed to evaluate a contamination level of the ion implanting apparatus 100. The contamination level of the ion implanting apparatus 100 may be represented in terms of the concentrations (e.g., the number of impurity atoms per unit of area) of the impurities 134 and 136 in the sample. In some embodiments, the step of analyzing the sample may be performed using an inductively-coupled-plasma mass spectrometer (ICP-MS). The use of the ICP-MS makes it possible to count the number of the second impurities 136 per unit of area of the wafer 10. The second impurities 136 being measured by this process may originate from an internal portion of the ion implanting apparatus 100 or from the cathode 132 of the ion source part 130. This means that the measured concentration of the second impurities 136 using this process can indicate effectively the contamination level of the ion implanting apparatus 100.

In a case where a semiconductor wafer is contaminated by second impurities 136, a semiconductor device fabricated using such a contaminated wafer may suffer from a chip failure; for example, the CIS chip may suffer from a white spot failure caused by the contamination. As described above, since the second impurities 136 may be produced from an internal portion of the ion implanting apparatus 100 or from the cathode 132 of the ion source part 130, to prevent wafer contamination it is necessary to periodically measure and monitor the contamination level of the ion implanting apparatus 100 using the processes described above.

According to some embodiments of the inventive concept, the first layer 20 may be formed on the wafer 10 by, for example, a diffusion process. Then, the wafer 10 with the first layer 20 is loaded into the ion implanting apparatus 100, an ion implantation process is performed, and the contamination level is measured. In this case, the second impurities 136 may be captured by the first layer 20 during the ion implantation process. Since the second impurities 136 captured in the first layer 20 can be easily detected, it is possible to improve reliability in measuring a contamination level of the ion implanting apparatus 100, and consequently to prevent failure of a semiconductor device which may be caused by the second impurities 136.

While exemplary embodiments of the inventive concepts have been particularly shown and described, it will be understood by one of ordinary skill in the art that variations in form and detail may be made therein without departing from the spirit and scope of the attached claims.

What is claimed is:

1. A method of measuring a contamination level of an ion implanting apparatus comprising the steps of:
providing a wafer;
forming a first layer on the wafer;
injecting impurities into the first layer using the ion implanting apparatus;
preparing an analysis sample by removing the first layer and concurrently collecting the impurities captured in the first layer from the wafer; and
analyzing the analysis sample.

2. The method of claim 1, wherein the step of forming the first layer on the wafer comprises performing a diffusion process on the wafer.

3. The method of claim 2, wherein the first layer is formed of a silicon oxide layer or a silicon nitride layer.

4. The method of claim 1, wherein the step of injecting impurities into the first layer comprises loading the wafer provided with the first layer into an ion implanting apparatus and performing an ion implantation process on the wafer.

5. The method of claim 4, wherein the impurities comprise metallic elements produced in the ion implanting apparatus.

6. The method of claim 5, wherein the ion implanting apparatus comprises an ion source part and a cathode provided in the ion source part, and the impurities comprise metallic elements that originate from the cathode.

7. The method of claim 6, wherein the impurities comprise at least one of tungsten (W), iron (Fe), molybdenum (Mo), nickel (Ni), aluminum (Al), cadmium (Cd), or copper (Cu).

8. The method of claim 6, wherein some of the impurities are cationized in the ion source part and are injected into the first layer during the step of injecting impurities.

9. The method of claim 4, wherein during the ion implantation process, some of the impurities are cationized and are captured by the first layer.

10. The method of claim 1, wherein the step of preparing an analysis sample comprises:
dissolving the first layer containing the impurities with a solution; and
collecting the solution, in which the impurities are dissolved, from the wafer.

11. The method of claim 10, wherein the solution comprises at least one of hydrofluoric acid (HF), hydrochloric acid (HCl), nitric acid (HNO₃), or hydrogen peroxide (H₂O₂).

12. The method of claim 1, wherein the step of analyzing the analysis sample comprises measuring a concentration of the impurities in the analysis sample.

13. The method of claim 12, wherein the step of analyzing the analysis sample is performed using an inductively-coupled-plasma mass spectrometer (ICP-MS).

14. In a method for periodically monitoring the contamination level of an ion implanting apparatus used to implant ions in a semiconductor substrate, the method comprising: periodically placing a substrate having a dissolvable, impurity-absorbing layer on a substrate surface in the ion implanting apparatus; subjecting the substrate surface with the dissolvable layer thereon to an ion implantation process using the ion implantation apparatus; capturing impurities from the ion implanting apparatus in the dissolvable layer; removing the dissolvable layer, together with any captured impurities, from the substrate by dissolving the layer in a solvent; and, measuring the concentration of impurities in the solvent containing the dissolved impurity-absorbing layer.

15. The method of claim 14 wherein the substrate is a silicon wafer, the dissolvable, impurity-absorbing layer is formed of silicon oxide or silicon nitride, and the solvent is selected from the group consisting of hydrofluoric acid, hydrochloric acid, nitric acid, hydrogen peroxide and mixtures thereof.

16. The method of claim 14 wherein the thickness of the dissolvable, impurity-absorbing layer is about 100 Å or greater.

17. The method of claim 14 wherein the concentration of impurities in the solvent containing the dissolved layer is measured using an inductively-coupled-plasma mass spectrometer (ICP-MS).

18. A method for fabricating a semiconductor device that includes a semiconductor wafer that is doped using an ion implanting apparatus, the method comprising the steps of: measuring the contamination levels of one or more ion implanting apparatuses according to the method of claim 1; selecting an ion implanting apparatus that demonstrates no or a very low contamination level; and, preparing the doped semiconductor wafer using the ion implanting apparatus with the very low or no contamination level.
